(19) United States
(12) Patent Application Publication
(10) Pub. No.: US 2024/0181573 A1
(43) Pub. Date: Jun. 6, 2024

(54) CUTTING METHOD FOR POLYMER RESIN MOLD COMPOUND BASED SUBSTRATES AND SYSTEM THEREOF

(71) Applicant: GENUINE SOLUTIONS PTE. LTD., Singapore (SG)

(72) Inventors: Sardjono CHAINUR, Singapore (SG); Zhongke WANG, Singapore (SG)

(73) Assignee: GENUINE SOLUTIONS PTE. LTD., Singapore (SG)

(21) Appl. No.: 18/439,405

(22) Filed: Feb. 12, 2024

Related U.S. Application Data
(63) Continuation-in-part of application No. 16/492,408, filed on Sep. 9, 2019.
(60) Provisional application No. 62/557,891, filed on Sep. 13, 2017.

(51) Int. Cl. B23K 26/402; B23K 26/0622; B23K 26/10; B23K 26/70

(52) U.S. Cl. CPC B23K 26/402; B23K 26/0622; B23K 26/10; B23K 26/703

(57) ABSTRACT

The invention includes a system and method of using a laser for singulation of a polymer resin mold compound substrate into packages or chips by a laser ablation process. A metal jig used for holding the substrate includes trenches to allow the laser beam to penetrate during cutting. Built-in piping allows water to circulate in a base around the jig to cool the substrate during cutting. The laser beam can pass through a cutting nozzle along with compressed gas or air to cool the substrate and remove debris. A pulsed laser beam can be split into two beams for dual focal spots used in the high speed cutting process, so that a combination of passes at different speeds and laser parameters can be achieved. This allows single pass singulation of units at high speed.

### RELATED APPLICATIONS

This is a continuation-in-part application of prior filed U.S. non-provisional patent application Ser. No. 16/492,408, filed Sep. 9, 2019, which is a national stage of PCT/SG2018/050467 filed Sep. 13, 2018, which claims priority to U.S. provisional patent application No. 62/557,891, filed Sep. 13, 2017. The contents of these applications are incorporated herein by reference.

### FIELD OF THE INVENTION

The present invention relates to singulation of polymer mold compound substrates. More specifically, it relates to a method of singulation integrated circuit (IC) packages using laser ablation to remove debris.

### BACKGROUND

Integrated Circuit (IC) packages are common in consumer products, automotive devices, memory, analog ICs, and microcontrollers. They power modern-day consumable and commercial electronic devices ranging from mobile phones, TV, household appliances to instruments in hospitals, transportation, solar energy, manufacturing industries, etc. The packages have evolved technologically for robust reliability and great improvement on performance.

IC packages are typically composed of polymer resin mold compound substrates with a copper lead frame shaped in a strip. The copper lead frame can be coated with pre-plated lead frame (PPF) (Ni/Pd) or with tin (Sn) plating. Polymer resin mold compound-based substrates are often epoxy mold compounds (EMC). Various raw material ingredients are added to an epoxy molding compound for reliability, improved physical properties and moldability. Examples of such ingredients include epoxy resins, phenolic resins, fused silica as filler, coupling agents, curing promoter, glass fibers and a release agent. These materials can influence the adhesion strength and moldability of the resulting product. The epoxy resin-based materials are used to encapsulate many types of electronic packages, from capacitors and transistors to central processing units (CPUs) and memory devices, such as Small Outline Transistor (SOT) packages, Small-outline IC (SOIC), Small-outline Package (SOP), Quad-Flat No-leads (QFN) packages, Dual-Flat No-leads (DFN) packages, Dual-in-line (DIP) packages etc.

Singulation of IC package is an essential step in the production of microelectronic chips and electronic devices. Singulation of IC packages is conventionally done by mechanical saw. Disadvantages of this method are high consumable cost, low cutting speed (i.e., 30 mm/s), wet process, copper smearing, chipping of IC package and dimension consistency due to mechanical tool wear. Efforts in the semiconductor industry have focused on pursuing improved singulation methods.

Typical methods of singulation use a diamond saw to cut a wafer into individual dies. However, diamond sawing of epoxy molding compound packages have limitations. For example, edge chippings, edge cracks, copper smear, edge copper burr and solder bridging, etc. are common issues. Further, when cutting with a wet chemical slurry current leakage is a risk. Other issues include a high cost of the mechanical saw, saw wear caused unstable chip dimensions and slow singulation speed, etc. Further, diamond sawing is only suited to cutting straight lines.

Laser sawing has emerged as an attractive alternative to mechanical methods for singulating IC packages. Laser-based singulation is a “non-contact process” as there is no tool wear nor mechanical stress on the work piece. Moreover, laser cutting can yield more consistent results.

However, laser sawing methods also have limitations. Heat generated by lasers is often a significant concern. Thermal effects from laser heat can cause edge thermal damage, material burning and ablation caused by the ejected material. A need, therefore, exists for an improved laser cutting system and method for polymer resin mold compound based substrates using laser that overcome these limitations. The method should provide uniform singulation while requiring less time than conventional techniques. The method should allow for high speed singulation without edge thermal effect, edge chippings, edge cracks, copper smear, edge copper burr and solder bridging, etc. The invention includes methods that use dual focused laser beams at high speed (i.e., 1-20 m/s) for singulation of mold compound packages. The methods described herein resolve the issues addressed above by providing a system for uniform singulation that requires less time and maintains a narrower scribe line.

### SUMMARY OF THE INVENTION

The following summary is provided to facilitate an understanding of some of the innovative features unique to the disclosed embodiment and is not intended to be a full description. A full appreciation of the various aspects of the embodiments disclosed herein can be gained by taking into consideration the entire specification, claims, drawings and abstract as a whole.

Embodiments include a system for singulation of a polymer resin compound into packages by a laser ablation process. The system can include a laser, a buffer station and a jig for holding the polymer resin compound.

An aspect of the invention is a system and method of laser singulation of a polymer resin mold compound package or substrate into packages or chips by a laser ablation process.

In aspects, vacuum pressure holds the polymer resin compound to the jig. In aspects, the laser is a pulsed laser with a repetition rate of 10 KHz and above up to 100 MHz.

In aspects, the pulsed laser is focused though a galvanometer scanner with a F-theta lens, a set of optics (rather than a single conventional focal lens). In aspects, the laser can be more effectively split into a dual focal spot (rather than a single focal spot).

The buffer station can include a heating element, optionally with a gas injector for emitting fast-cooling gas. A source of compressed air or gas can force compressed air or gas in the direction of the laser.

In aspects, the laser cuts along trenches that are embedded in the jig and the jig is cooled by circulating a liquid through a base plate with a system of internal pipes. The trenches can have a depth of approximately 1 to 3 centimeters and a width greater than or equal to 1 millimeter. In an alternative design, the trenches have a width greater than or equal to 0.5 mm.

Another aspect of the invention is a laser cutting method that uses pulsed dual laser beams through galvanometer scanner and multiple combinations of passes at different speeds of 1-20 m/s and laser parameters (i.e. sequential cuts).

Another aspect of the invention is a laser cutting method that uses multiple sequential cuts, as multiple passes deliver an optimum combination of high throughput and edge quality.

Another aspect of the invention is a laser cutting method that uses a cutting jig with trenches along which a polymer resin compound is cut.

Another aspect of the invention is a laser cutting method that uses a base plate with internal pipes for circulating a liquid to cool the cutting jig and attached substrate/chips.

Embodiments also include a method of singulation of a polymer resin compound into packages by a laser cutting process. The method can includes steps of (a) loading the polymer resin compound onto a cutting jig, (b) activating a vacuum to secure the polymer resin compound to the cutting jig, (c) activating a pulsed dual laser spots to cut the polymer resin compound at high speed above 1-20 m/s along a series of trenches that are embedded in the cutting jig and (d) circulating a liquid through a base plate of the cutting jig to cool the polymer resin compound.

The method can include an additional step of pre-heating the substrate at a buffer station and optionally injecting fast-cooling gas before loading it onto the cutting jig. Pressurized air or gas can be used to cool the ablated area and/or remove debris. The packages can be delivered to a cleaning station after they are cut.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the disclosure is not limited to specific methods and instrumentalities disclosed herein. Moreover, those in the art will understand that the drawings are not to scale. Wherever possible, like elements have been indicated by identical numbers.

FIG. 1A depicts a substrate and a dual laser beam used for singulation.

FIG. 1B depicts a galvanometer scanner with an F-theta lens and a set of optics.

FIG. 2A is a flow chart that lists the steps of a laser cutting method of singulation of a polymer resin mold compound package or substrate into chips by a laser ablation process.

FIG. 2B is a flow chart that lists the steps cleaning chips after the laser ablation process.

FIG. 3A depicts a buffer station and a top view of a cutting jig without packages or substrates loaded on it.

FIG. 3B depicts a front view of a cutting jig without packages or substrates loaded on it.

FIG. 4A depicts side views of a cutting jig.

FIG. 4B depicts close-up view of a vacuum hole.

FIG. 5 depicts the direction of chilled water that circulates through the base plate on which the cutting jig is mounted to cool the cutting jig.

FIG. 6A shows a strip package of Interposer attached with OLGA.

FIG. 6B shows singulation at a first step.

FIG. 6C shows singulation at a second step.

FIG. 6D shows singulation at a third step.

FIG. 6E shows singulation at a fourth step.

FIG. 6F shows individual packages after singulation.

FIG. 6G shows edges of individual packages after singulation.

FIG. 7A shows edges of individual packages after singulation.

FIG. 7B shows individual packages after singulation.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present disclosure. Also, common but well-understood elements that are useful or necessary in a commercially feasible embodiment are often not depicted in order to facilitate a less obstructed view of these various embodiments of the present disclosure.

### LIST OF REFERENCE NUMBERS

200 cutting jig (top view)
202 cutting jig
203 heated plate
204 strip surrounding rail
205 buffer station
207 gas injector
210 cutting jig (front-side view)
220 cutting jig (side view)
230 cutting jig (cross-sectional view 1)
240 cutting jig (cross-sectional view 2)
305 direction of laser movement
310 outlet of the gas tube
315 scribe line or singulation street
320 two laser ablation spots
320 laser focal spot 1
322 laser focal spot 2
325 top of packages
326 individual packages (chips or units)
328 beam splitter (diffraction optical element, DOE and moveable horizontally)
330 Galvonometer scanner
332 Galvo scan mirror 1
333 f-theta focal lens
334 Galvo scan mirror 2
336 laser beam 1
338 laser beam 2

### Definitions

While the invention is primarily described for the singulation of an epoxy molding compound, it is understood that the invention is not so limited and can be used to assist with other endeavors that require precise shaping and molding of small components. And while reference is made to a polymer resin compound, the technology is easily transferable to other substrates. The particular values and configurations discussed in these non-limiting examples can be varied and are cited merely to illustrate at least one embodiment and are not intended to limit the scope thereof.

Reference in this specification to “one embodiment/aspect” or “an embodiment/aspect” means that a particular feature, structure, or characteristic described in connection with the embodiment/aspect is included in at least one embodiment/aspect of the disclosure. The use of the phrase “in one embodiment/aspect” or “in another embodiment/aspect” in various places in the specification are not necessarily all referring to the same embodiment/aspect, nor are separate or alternative embodiments/aspects mutually exclusive of other embodiments/aspects. Moreover, various features are described which may be exhibited by some embodiments/aspects and not by others. Similarly, various requirements are described which may be requirements for some embodiments/aspects but not other embodiments/aspects. Embodiment and aspect can be in certain instances be used interchangeably.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way.

Consequently, alternative language and synonyms may be used for any one or more of the terms discussed herein. Nor is any special significance to be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Without intent to further limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions, will control.

The term “galvanometer scanner laser” refers to laser beam movement that is controlled through a galvanometer scanner. The scanner contains two galvo scan mirrors that deflect an incident laser beam in X and Y. After the two scan mirrors, there is a focal lens to focus the laser beam. The executing of the two-axis motions, both moving up and down, as well as moving back and forth, leads to scanning of the laser beam for singulation of a substrate. The focused beam after the galvo scanner is used to singulate a substrate.

The term “beam splitter” refers to diffraction optical element (DOE) to split the single laser beam into two beams. The DOE horizontally move back and forth can control the distance between the dual focal spots. The DOE approaches close to the galvanometer scanner, the dual spots getting closer, thus the cutting kerf narrow. The DOE goes away from the galvanometer scanner, the distance of the dual spots getting larger, thus the cutting kerf wider. The dual spot distance far or close can control the package cutting kerf width and thus the package size.

The term “kerf” refers to narrow channel left behind by a saw singulation, and (relatedly) the measure of its width. The term “singulation” refers to a process of “cutting” or “dicing”. The process can involve scribing and breaking, mechanical sawing or laser cutting. Singulation kerf width depends on several factors including the width of the saw blade, the set of the blade's teeth, the amount of wobble created during cutting and the amount of material pulled out of the sides of the cut. When using a laser, the kerf is dependent upon the properties of the material being cut, the workpiece thickness, the lens focal length and the type of cutting gas used in the laser.

The term “laser ablation” refers to the process of removing material from a solid surface by irradiating it with a laser beam. At a laser flux, the material is heated by the absorbed laser energy and evaporates or sublimates.

The term “organic land grid array” or “OLGA” refers to a leadless package with air cavity and organic substrate with patterned conductive traces. ASIC and LEDs with different wavelengths are integrated in the package depending on specific applications. Connections are made through the leads (terminal pin) on the bottom surface of the package. These leads can be directly soldered onto the PCB.

Other technical terms used herein have their ordinary meaning in the art that they are used, as exemplified by a variety of technical dictionaries. The particular values and configurations discussed in these non-limiting examples can be varied and are cited merely to illustrate at least one embodiment and are not intended to limit the scope thereof.

### DETAILED DESCRIPTION OF THE INVENTION

It is to be understood that both the foregoing general description and the following detailed description are exemplary and explanatory and are intended to provide further explanation of the subject technology as claimed. Additional features and advantages of the subject technology are set forth in the description below, and in part will be apparent from the description, or may be learned by practice of the subject technology. The advantages of the subject technology will be realized and attained by the structure particularly pointed out in the written description and claims hereof.

Packaging preparation typically includes substrate mounting followed by substrate dicing or cutting. The substrate is typically a polymer resin mold compound. The invention utilizes vacuum pressure to mount a substrate onto a cutting jig. Thereafter, laser technology is used to cut the substrate into sections (i.e. called as individual packages, units or chips).

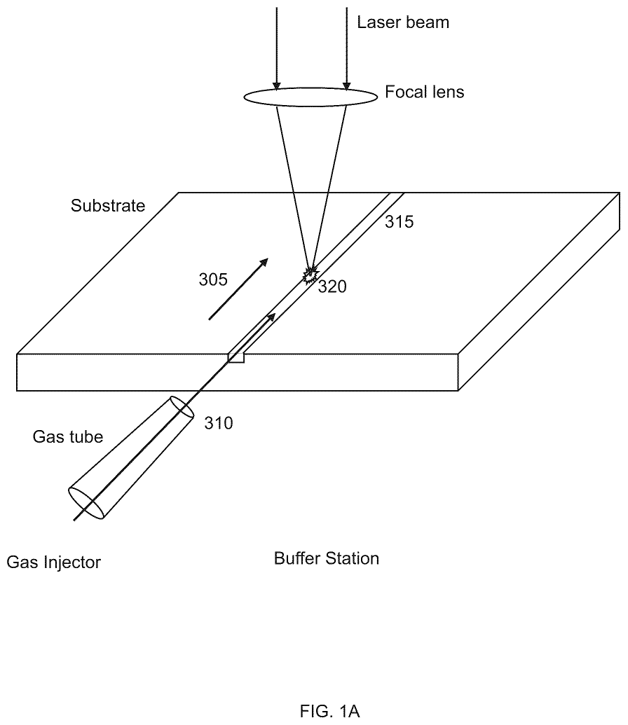

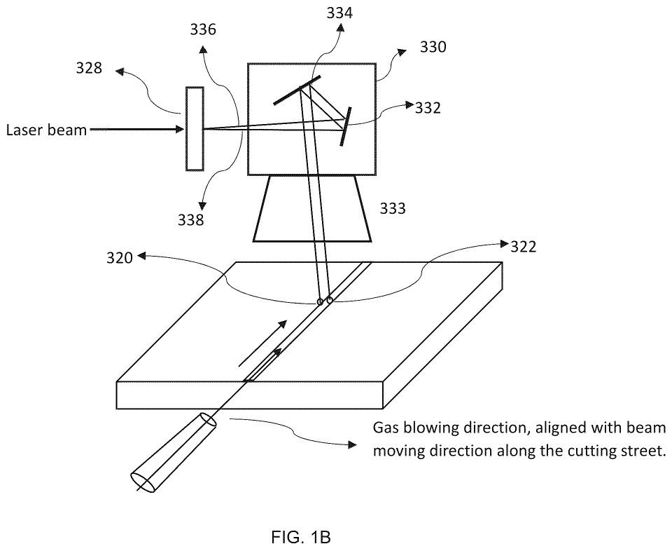

FIG. 1A depicts a substrate being cut by a dual focused laser ablation. The laser beam moves in a direction depicted by the arrow 305. The scribe line or singulation street 315 is formed by the laser at high singulation efficiency. The high speed reduces the interaction time between laser and substrate. The edge thermal effective can be reduced or eliminated. The defects appeared in diamond blade saw and conventional laser sawing can be resolved. The laser is directed over the substrate multiple times (i.e. multiple passes) to separate the substrate into individual packages free of cutting edge defects. A pulsed laser beam can be used with a combination of passes at different speeds and laser settings. This allows single pass singulation of units at high speed.

A gas tube is also depicted. The outlet of the gas tube 310 directs gas or compressed air in a direction parallel to the singulation street. This cools the substrate and removes particles or debris that result from the cutting process. As depicted, it is aligned with the direction of beam movement along the cutting street.

A metal jig can hold the substrate while it is cut (not shown). The jig includes trenches to allow the laser beam to penetrate during cutting. Further, the jig can use water to cool the substrate. Built-in piping in a base plate can allow water to circulate and cool the substrate during cutting by drawing away heat from the jig.

FIG. 1B depicts the system along with an f-theta focal lens 333 and Galvonometer scanner 330. A f-theta focal lens directs the dual laser beam into two points of contact the substrate at the two laser ablation spots 320. The galvanometer scanner is able to scan the laser beam at high speed 1-20 m/s instead of the x-y stage moving which is usually not able to move at high speed above 1 m/s.

A laser beam is directed into a beam splitter 328. Thereafter, two laser beams (336, 338) are directed into the Galvonometer scanner 330. The beam is reflected from a first Galvo scan mirror 332 to a second Galvo scan mirror 334. The beam is directed to a first laser focal spot 320 and a second laser focal spot 322. Thereafter, the laser beams pass through the f-theta focal lens 333. The dual laser beams are focused on two points of contact the substrate (i.e., two laser ablation spots, 320, 322).

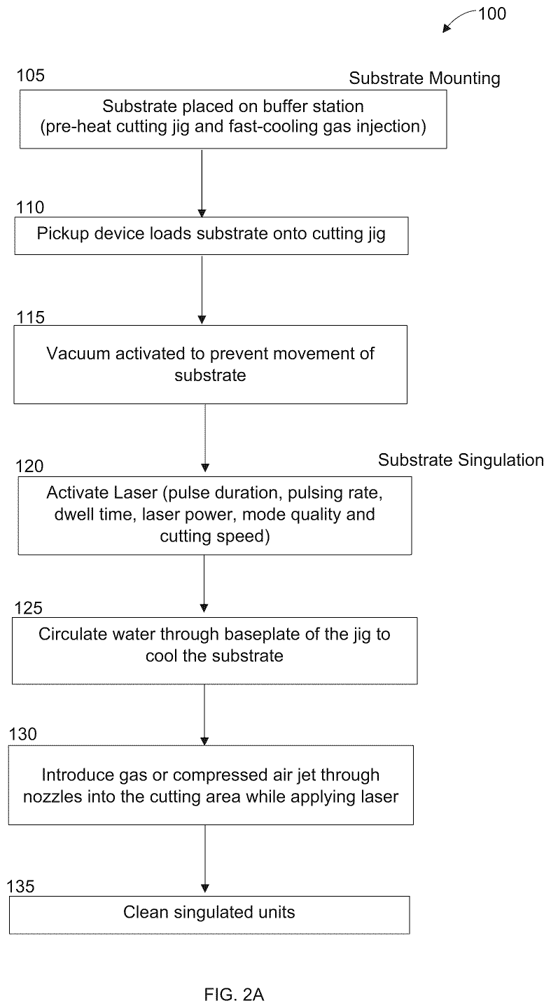

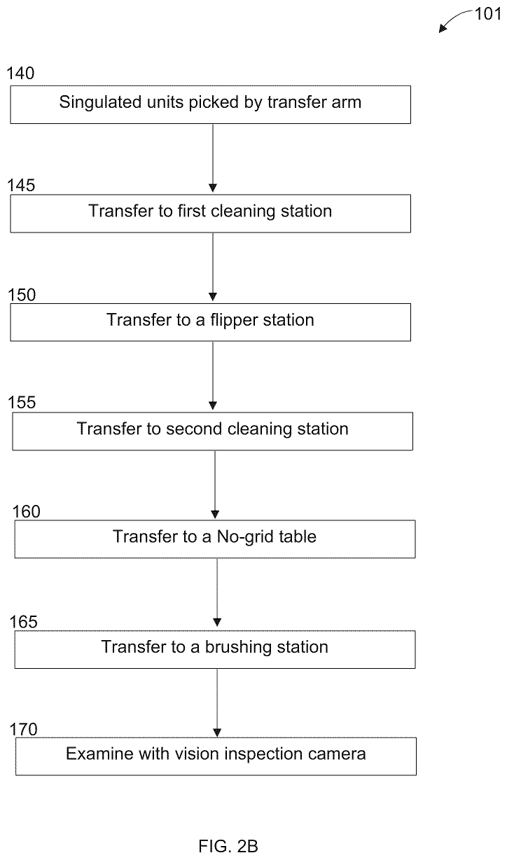

FIG. 2A is a flow chart 100 of a laser cutting method of singulation of a substrates into individual packages/units by a laser ablation process, according to one embodiment. The process can be separated into substrate mounting and substrate singulation. A picker (pick and place machine or robot) can be used to move the substrate and/or singulated units.

At step 105, the substrate is placed on a buffer station 205. The buffer station 205 can include a heated plate 203 to pre-heat the substrate with optional injection of fast-cooling gas before placement on the cutting jig. The fast-cooling gas can cool the heated polymer resin quickly such that the form it has taken after pre-heating is preserved before loading the polymer resin compound onto the cutting jig. This step can release warpage on the substrate before it is placed on the cutting jig which ensures a good vacuum seal and a constant laser beam focus Z-height on the substrate due to free of warpage distortion.

Thereafter, the pickup device can load the substrate onto the cutting jig (“jig”) from the buffer station 205. The cutting jig firmly holds the substrate while it is cut into individual chips. The substrate can be secured by vacuum pressure. Step 115 depicts the activation of vacuum to create a suction force upon the substrate and prevent movement. Vacuum holes can be round (square units) or oblong (rectangular units).

The cutting jig can be built with a metal based material such as Steel Use Stainless (SUS) or Aluminum. The bottom portion of the jig can include a vacuum chamber for suction on units during cutting, thereby avoiding movement of the units. Each unit can rest on an island cut out from the cutting jig and supported with a layer of rubber 0.2 mm-1.0 mm thick (preferably around 0.5 mm thick) to prevent scratches/damage on surface of the units.

Cutting (“singulation”) is the next step 120 which is preferably performed with the substrate facing downward. The laser can cut the substrate into individual chips using a pulsed laser beam. A pulsed laser beam is used so that the substrate is cut using multiple passes at different speeds and laser parameters. This helps maintain the substrate at a lower temperature and prevents warping due to less thermal heating from the laser beam.

Debris from the cutting process can be removed using compressed air (e.g. N₂, Ar, or CO₂) that is introduced through nozzles 310 into the cutting area. Nozzles can be located strategically to introduce the compressed air so that it is aligned parallel to the laser cutting street. The debris can be exhausted away from bottom of chamber. Debris and fumes generated during cutting can be removed through exhaust openings located at the sides and bottom of the jig (not shown). The compressed air can also help cool the cutting street, particularly at the laser contact area and to prevent “sparking” of the laser upon contact with the substrate.

Excess heat is a common problem presented with conventional methods of laser singulation. To overcome this issue, the jig can include a system for circulating chilled water to cool the substrates during cutting 125. In aspects, the temperature of chilled water is below 22 degrees Celsius (preferably around 10 degrees Celsius or lower). This cools the units during cutting, effectively transferring thermal heat generated by laser away from cutting area.

Gas or compressed air can be introduced through the nozzle onto the cutting area 130. The laser beam can pass through a cutting nozzle along with compressed gas or air. This allows single pass singulation of units at high speed. After cutting, the singulated units held in cutting jigs can be cleaned to remove debris and dislodge cutting burrs/fibers left on the surface of units 135. A vent can be activated to blow away debris that accumulates or settles during singulation. The cleaning process can include additional steps such as brushing to produce singulated units that are free of debris.

FIG. 2B is a flow chart 101 of the cleaning steps 101 for an automatic machine according to one embodiment. The units are picked by a vacuum transfer arm 140 and transferred to a first cleaning station 145. At the first cleaning station, the top sides of the units are cleaned with a soft cloth/sponge soaked lightly in an alcohol solution (e.g. IPA) or plain deionized (DI) water. Next, the units are transferred to a flipper station 150, flipped 180 degree and picked by another transfer arm. They are next transferred to second cleaning station 155 for cleaning. As with the first cleaning station, an alcohol solution such as IPA or DI water can be used. Here, the bottom sides of the units are cleaned. Next, the units are transferred to a no-grid table 160 where the units are transported on the table to pickers' pickup position. Rotating picker heads can pick each unit and transfer each to a brushing station 165 so that the units are brushed at all four sides. The units are then transferred through a vision inspection camera 170 and offloaded onto a tray. Remaining scrap rail can be removed automatically by another picker arm to be disposed to a scrap bin (not shown).

### Cutting Jig

In a preferred method, a cutting jig firmly holds the substrate during singulation. Structural characteristics of the jig allow the substrate to be cut precisely without reaching high temperatures that can cause warpage or other damage. Trenches (i.e. indented regions in the jig) are embedded to allow the laser beam to penetrate during cutting. A base with internal piping allows chilled water to be circulated through the base plate. This removes heat from the jig to cool the substrate during cutting.

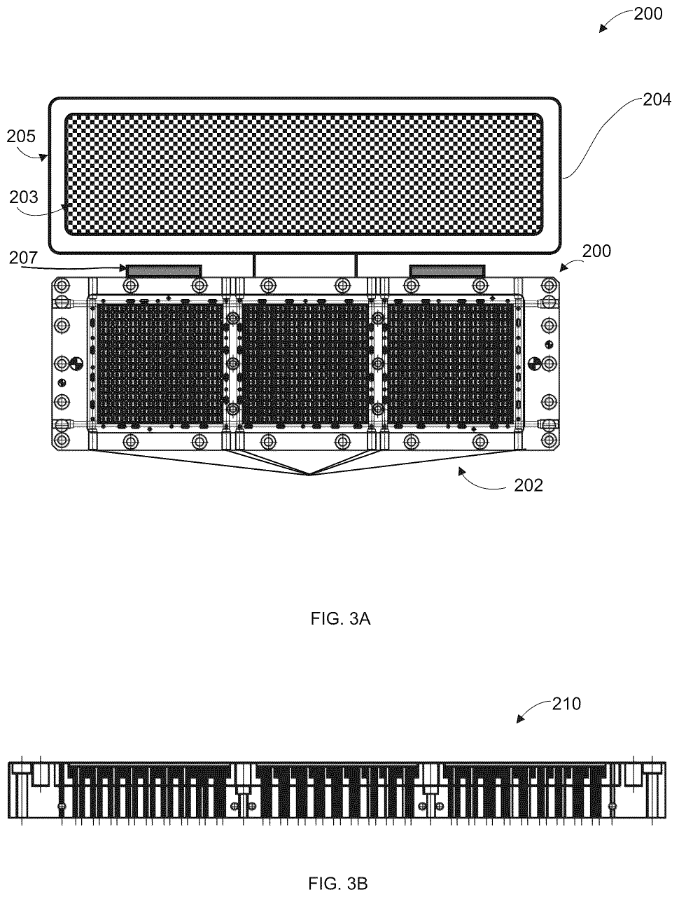

FIG. 3A depicts a buffer station 205 and a top view of a cutting jig 202 used in the methods described herein. The trenches form a grid in the center portion. A substrate is placed over the cutting jig. The laser is directed to cut along the trenches to form individual packages from the substrate. The buffer station 205 includes a heated plate 203 and gas injector 207 in relation to the jig. FIG. 3B depicts a front-side view 210 to further illustrate the trenches in the jig (narrow white vertical lines). In aspects, the trenches have a depth of approximately 1 to 3 centimeters and a width greater than or equal to 1 millimeter.

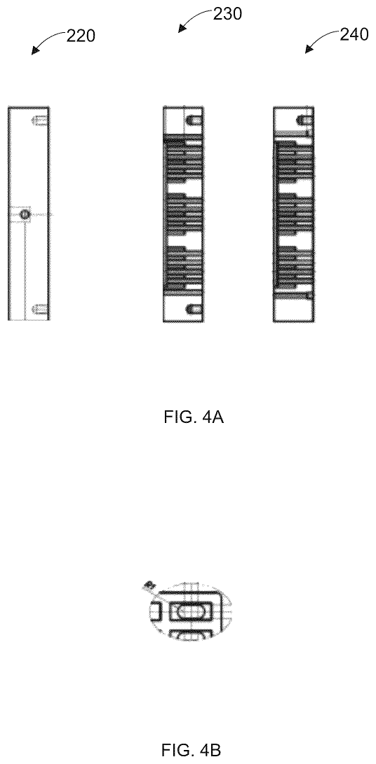

FIG. 4A depicts additional views of the jig, including a side view 220 and cross-sectional views 230 and 240 taken at different regions of the cutting jig. FIG. 4B depicts a detailed portion of a vacuum hole.

The strip surrounding rail (i.e. the perimeter of the strip without any units) can be supported by the jig, located with pins, and held in place by vacuum. Two separate vacuum lines are provided, one to hold onto the strip rail and another to secure individual units. Surrounding each unit are trenches cut into the metal jig, each of depth 1 cm-3 cm (preferably around 2 cm or more) and width of minimum (units cutting kerf width+X mm). Where X value depends on each unit width and length dimension, at least (greater than or equal to) 0.5 mm (preferably 1 mm). The trenches are designed for a laser beam to penetrate during cutting and to collect debris generated from cutting. The tranches can be cleaned with high pressure air after each strip cutting. The vacuum holes can have shapes such as round (for use with square units) or oblong (for use with rectangular units).

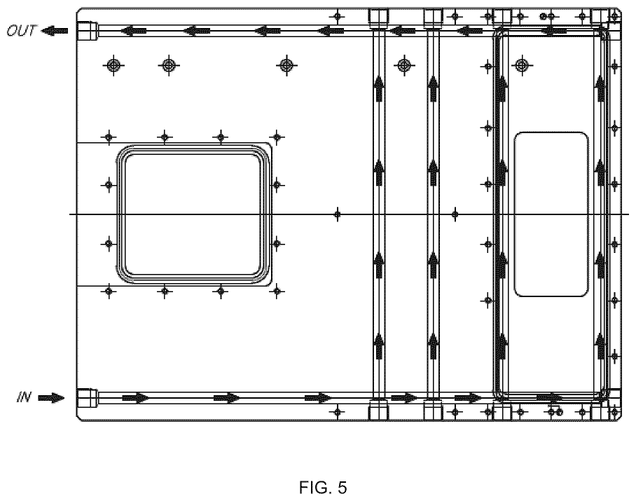

Water or another fluid can be used to cool the substrate during singulation. FIG. 5 depicts a base plate on which the cutting jig can be mounted. Chilled water is circulated through the base plate to cool the cutting jig and attached substrate. The arrows show the direction of water flow through a series of tubes or pipes.

The cutting jig can be fully enclosed in a cutting chamber. Debris and fumes generated from cutting can be exhausted through multiple exhaust openings located at the sides and bottom of the chamber. Further, an air blow at the top of the chamber can be directed at debris that has accumulated or settled on mechanical parts inside the chamber. This allows the debris to be exhausted out of the bottom of the chamber. Nitrogen, Carbon dioxide or compressed air can be used for this purpose. The nozzles can be placed so that the compressed air is aligned parallel to the laser cutting area. This helps cool the cutting area as well as clearing debris to minimise sparking of laser upon contact with subject material.

### Laser

One of two types of laser head design can be used for singulation. One design type is a laser beam split into two beams, a diffraction optical element (DOE) splitting the single beam, double line/two line cutting can be achieved at the same time. The other is that the high speed 1-20 m/s beam scanning can be controlled through Galvanometer Scanner. As addressed above (e.g., at par. [0048]), the diffraction optical element (DOE) can horizontally move back and forth to control the distance between the dual focal spots. As the DOE approaches close to the galvanometer scanner, the dual spots get closer thus the cutting kerf narrow. As the DOE is moved away from the galvanometer scanner, the distance of the dual spots gets larger thus the cutting kerf wider. The dual spot distance far or close can control the package cutting kerf width and thus the package size. A single beam can achieve the similar results as the dual/twin beams (dual beam singulation, or dual beam cutting), however, a single beam must be scanned twice respectively following the two beam spots' position. Compared to a single beam, the dual beam can significantly increase the ablation efficiency to improve the material removal efficiency. The singulation efficiency can significantly increase through galvanometer scanner high speed scanning and double line cutting with dual spot ablation.

A focal lens is used to allow vertical penetration of a laser beam into the surface of the substrate. Depending on the beam power intensity and its distribution on the substrate to be cut, the focal lens can be a conventional focal lens, a F-theta focal lens or a telecentric lens. For general singulation applications, a F-theta focal lens is sufficient for a scanning field of 100 mm by 100 mm or smaller. This method allows for laser beam to shape the substrate with a combination of passes at different speeds and laser parameters. In the alternative, a cutting nozzle can be used with compressed gas (N₂/CO₂) or air. This allows single pass singulation of units at high speed.

In a preferred method, the invention uses laser for cutting, as it is low cost, requires free/minimal maintenance and meets other criteria for the cutting process. However, the cutting approach should include efforts to efficiently produce substrates with high quality edges.

To optimizing edge quality of substrates, peripheral heating should be minimized. This means maximizing the proportion of the total laser power that is delivered above the ablation threshold for the materials. One way to do this is to use a laser with short pulse duration and pulses with fast rise time. The heat created by each pulse is small and has time to dissipate before the next pulse arrives. In this regard, a pulsed laser is preferred rather than a Continuous-Wave (CW) laser. The pulsed laser can be a Nanosecond (ns), Near Infra-Red (NIR) laser (such as Nd:YAG laser or fiber laser) or Pulse width tunable ns NIR lasers (such as pulse width from 1 ns to 500 ns) with a power of 10-200 Watts, a ultrashort pulsed laser (such as pulse width from a few ps to 1 ns). The laser can be applied in a multi-line and multilayer process.

The singulation process can use a laser soft ablation technique to remove the materials. Achieving high edge quality requires a number of laser parameters to be optimized for the exact needs of singulation. The parameters include laser pulse duration, pulsing rate, dwell time, laser power, mode quality and cutting. The singulation process can be improved with periodic parameter changes. A high repetition rate “cleaning pass” can improve the kerf finish.

With regard to limiting peripheral thermal effects, spatial confinement of the laser pulse can be as important as temporal confinement. It can be crucial to use a laser beam that can be focused to a small intense spot rather than a diffuse area. This type of spot is obtained by designing the laser to produce Transverse Electro Magnetic (TEM₀₀) single-mode output, where the beam has a round cross section whose power peaks in the center. As a general rule with lasers, it becomes increasingly difficult to maintain high mode quality as power is increased. However, singulation may require relatively high power levels to deliver the speed and cost-effectiveness to compete mechanical sawing. So the laser must be carefully designed to deliver this high power level together with TEM₀₀ output.

A high-pulse repetition rate can also be desirable. This enables fast sweeping of the laser beam across the material without producing a dotted line cut. For package singulation, a repetition rate below 10 KHz will limit processing speed. For this reason, it is preferred to use a singulation laser with pulse repetition rates above 10 kHz.

In principle, the laser could cut through an entire package, even at 1 mm total thickness in a single cut. But the dwell time required to achieve this would cause a detrimental thermal effect (i.e. a rough burning edge). Better results can be obtained by cutting using multiple sequential cuts. For example, multiple passes may be ideal to deliver an optimum combination of high throughput and edge quality for a 1 mm thick package or above such as 1.2 mm thick.

### EXAMPLES

Singulation of Interposer Attached with OLGA

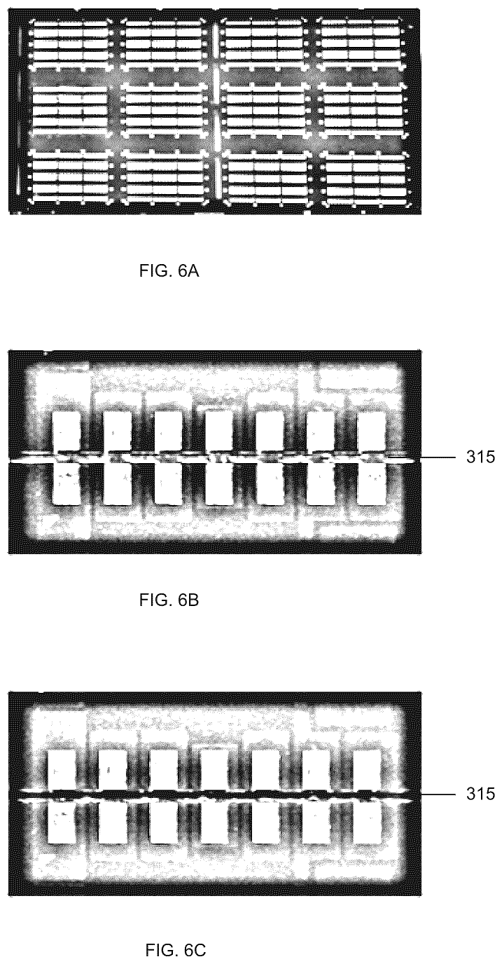

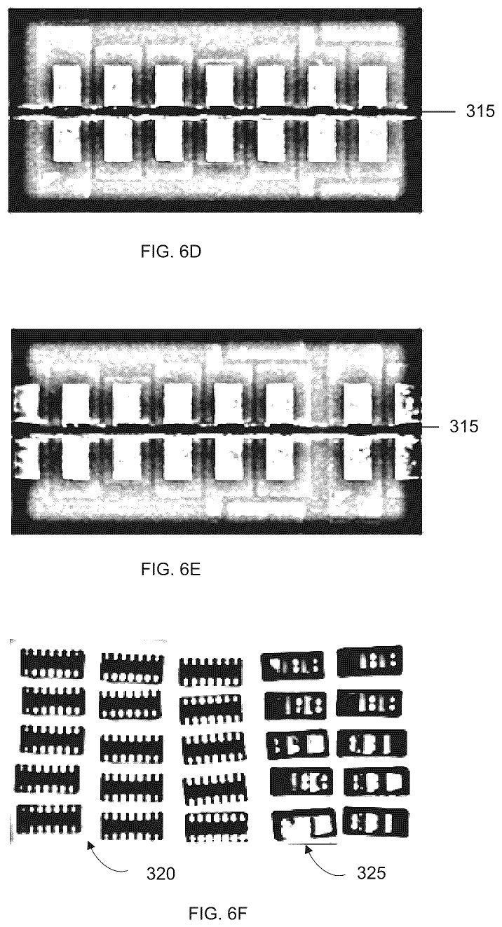

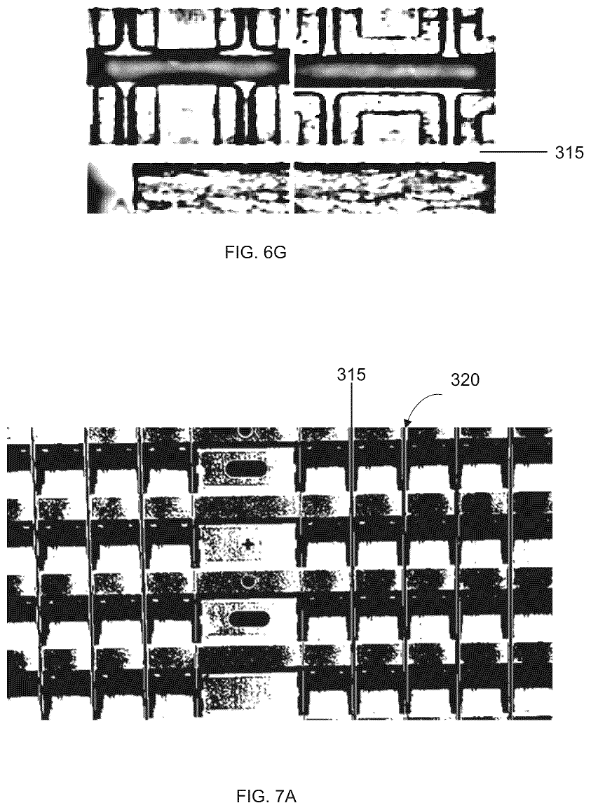

FIG. 6A depicts an example for laser singulation of a strip package of interposer attached with OLGA. A 100 nanosecond (ns) pulsed NIR fiber laser is used to singulate the resin mold (i.e. substrate) into packages. Multiple scans of the laser are used as described above. Three scans (i.e. lines) are used in this example. Each scan leads to a smoother, more complete singulation street 315 until the substrate is separated into individual packages.

The first scan is performed at a power 16 W, a speed of 300 mm/s and a frequency of 150 KHz. The singulation results are depicted in FIG. 6B. A straight, clean groove is formed along the singulation street 315. The second step is performed at a power 28 W, speed of 500 mm/s and a frequency of 150 KHz. The singulation results are shown in FIG. 6C. A certain cutting depth is generated free of edge burning in Step 2.

The third step is performed at a power of 68 W, a speed of 750 mm/s and a frequency of 150 KHz. The singulation results are shown in FIG. 6D. A straight, clean groove is formed along the singulation street 315. The fourth step is performed at a power 45 W, a speed of 750 mm/s and a frequency of 200 KHz. The singulation results are shown in FIG. 6E. The final singulation step is completed so that the substrate is separated into smaller packages, as shown in FIG. 6F. A view of the bottom of the packages is shown 320 along with a view of the top of the packages 325.

FIG. 6G depicts edges of individual packages after singulation. The chips have a clean top surface and a clean and straight sidewall.

### Singulation of Small Outline Transistor (SOT) Packages

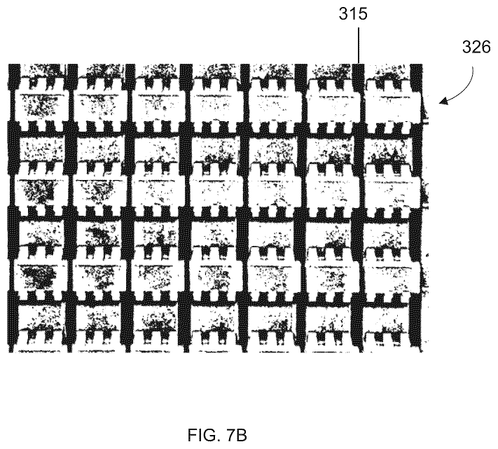

FIG. 7A depicts an example for laser singulation of a strip package of SOT. A picosecond (ps) pulsed laser is used to singulate the resin mold (i.e. substrate) into packages. Dual beams to produce two laser ablation spots 320, 322 are used to produce double cutting lines to cut the SOT packages along the singulation street 315. Multiple scans of the laser are used as described above. Seven scans are used in this example. Each scan leads to a smoother, more complete singulation street 315 until the substrate is separated into individual packages. The seven scans are performed at various power 50-300 W, speed 1-20 m/s and frequency of 100 KHz to 50 MHz.

FIG. 7B depicts the individual packages after singulation. The individual packages (chips or units) 326 have a clean top surface and a clean and straight sidewall. The chips 326 are located on the cutting jig after the singulation.

### Choice of Laser

A laser should be reliable, cost effective and sufficient to meet the cutting process. A pulsed laser is used rather than a CW laser. For example, an ns NIR fiber laser or Pulse width tunable ns NIR fiber laser with power of 10-200 Watts can be used. Other types of lasers such as an Nd:YAG laser and ps lasers can also be used.

### Singulation Process

Laser ablation can be used with a multi line, multilayer process. Periodic parameter changes can improve the speed of the process and the quality of the packages. Further, a high-repetition rate “cleaning pass” can improve the kerf finish.

While the present invention has been described in terms of particular embodiments and applications, in both summarized and detailed forms, it is not intended that these descriptions in any way limit its scope to any such embodiments and applications, and it will be understood that many substitutions, changes and variations in the described embodiments, applications and details of the method and system illustrated herein and of their operation can be made by those skilled in the art without departing from the spirit of this invention.

What is claimed is:

1. A system for singulation of a polymer resin mold compound-based substrate into packages by a laser ablation process comprised of:
a laser;
a buffer station comprising a heated plate to pre-heat the polymer resin mold compound-based substrate and a gas ejector for fast-cooling gas to cool the polymer resin mold compound-based substrate to preserve its form after pre-heating;
a jig for holding the polymer resin compound,
wherein the laser cuts along trenches that are embedded in the jig, and
wherein the jig is cooled by circulating a liquid through a base plate with a system of internal pipes, wherein a cutting nozzle that forces compressed air or gas in the direction of the laser to allow single pass singulation of units at high speed,
wherein a bottom portion of the jig comprise at least one vacuum chamber to allow suction on units during cutting,
wherein the laser is a pulsed laser beam.

2. The system of claim 1, wherein the laser is split into two beams.

3. The system of claim 1, wherein the laser is scanned with a galvanometer scanner.

4. The system of claim 1, wherein the laser is focused on a first ablation spot and a second ablation spot.

5. The system of claim 1, wherein the trenches have a depth of 1 to 3 centimeters and a width greater than or equal to 1 millimeter.

6. The system of claim 1, wherein the trenches have a width greater than or equal to 0.5 mm.

7. The system of claim 1, wherein vacuum pressure holds the polymer resin mold compound-based substrate to the jig.

8. The system of claim 1, wherein the laser is a pulsed laser with a repetition rate of 10 KHz and above.

9. The system of claim 1, wherein the laser is scanned at a speed of 1-20 m/s.

10. A method of singulation of a polymer resin mold compound-based substrate into packages by a laser cutting process comprised of steps of,
pre-heating the polymer resin mold compound-based substrate at a buffer station comprising a heated plate,
loading the polymer resin mold compound-based substrate onto a cutting jig,
activating a vacuum from at least one vacuum chamber to secure the polymer resin mold compound-based substrate to the cutting jig,
activating a pulse laser to cut the polymer resin mold compound-based substrate along a series of trenches that are embedded in the cutting jig,
ejecting pressurized air or gas through cutting nozzle in the direction of the laser to allow single pass singulation of units at high speed; and
circulating a liquid through a base plate of the cutting jig to cool the polymer resin mold compound-based substrate,
an additional step of injecting fast-cooling gas to cool the polymer resin mold compound-based substrate to preserve its form after pre-heating before loading the polymer resin mold compound-based substrate onto the cutting jig.

11. The method of claim 10, further comprising a step of using a beam splitter to split a laser beam from the pulse laser into a first beam and a second beam.

12. The system of claim 11, further comprising a step of focusing the laser beam with a galvanometer scanner.

13. The system of claim 11, further comprising a step of focusing the laser beam onto a first ablation spot and a second ablation spot.

14. The method of claim 10, further comprising a step of ejecting pressurized air or gas in the direction of the laser to cool an area ablated by the laser.

15. The method of claim 10, further comprising a step of ejecting pressurized air or gas in the direction of the laser to remove debris.

16. The method of claim 10, further comprising a step of exhausting debris and/or fumes through one or more exhaust openings along edges of the cutting jig.

17. The method of claim 10, further comprising steps of removing packages from the cutting jig and transferring the packages to a cleaning station.
